(19) United States
(12) Patent Application Publication
(10) Pub. No.: US 2015/0155451 A1
(43) Pub. Date: Jun. 4, 2015

(54) LIGHT EMITTING DIODE PACKAGE STRUCTURE

(71) Applicant: Lextar Electronics Corporation, Hsinchu (TW)

(72) Inventors: Zong-Han YU, Keelung City (TW); Yi-Lun LIN, Miaoli County (TW)

(73) Assignee: Lextar Electronics Corporation, Hsinchu (TW)

(21) Appl. No.: 14/280,694

(22) Filed: May 19, 2014

(30) Foreign Application Priority Data
Dec. 3, 2013 (TW) 102144252

(51) Int. Cl. H01L 33/52; H01L 33/58

(52) U.S. Cl. CPC H01L 33/52; H01L 33/58

(57) ABSTRACT

A light emitting diode package structure includes a substrate, a light emitting diode chip and a terminal connecting portion. The substrate has a first surface and a second surface that are opposite to each other, and a side surface surrounding and connecting the first surface and the second surface. The first surface has a predetermined die bonding area and the light emitting diode chip is disposed on the die bonding area. The terminal connecting portion protrudes from the side surface and is electrically connected to the light emitting diode chip.

### RELATED APPLICATIONS

This application claims priority to Taiwan Application Serial Number 102144252, filed Dec. 3, 2013, which is herein incorporated by reference.

### BACKGROUND

1. Field of Invention

The present invention relates to a light emitting diode, More particularly, the present invention relates to a light emitting diode package structure.

2. Description of Related Art

At present, after packaging the light emitting diode chip and the substrate, it is required to fix the entire light emitting diode package structure on the circuit board, surface mount technology (SMT) process or soldering. Whether by either the soldering or SMT process, both of them require an operation of soldering under high temperature, which is usually higher than 260 degrees Celsius.

Such high temperatures usually incur the issue of cracking or deterioration in the encapsulant material as well as the substrate of the light emitting diode package structure, rendering inferior performance of the light emitting effect of the light emitting diode package structure. In addition, if the soldering is manually carried out, the light emitting diode package structure will most likely has a poor quality from improper soldering position or solder-ball size control. On the other hand, the application of the SMT process results in high manufacturing cost problem.

### SUMMARY

One aspect of the invention is to provide a light emitting diode package structure to solve the problems of the prior art.

According to one embodiment of the invention, a light emitting diode package structure, which includes a substrate, a light emitting diode chip and a terminal connecting portion is proposed. The substrate has a first surface and a second surface that are opposite to each other, and a side surface surrounding and connecting the first surface and the second surface, and the first surface has a predetermined die bonding area. The light emitting diode chip is disposed on the die bonding area. The terminal connecting portion protrudes from the side surface of the substrate and is electrically connected to the light emitting diode chip.

According to another embodiment of the invention, a light emitting diode package structure, which includes a substrate, a light emitting diode chip and a terminal connecting portion is proposed. The substrate has a first surface and a second surface that are opposite to each other, and a side surface surrounding and connecting the first surface and the second surface, wherein the first surface has a predetermined die bonding area, and the side surface has a first notch. The first notch has a first side, a second side, and a third side, wherein the first side and the second side are opposite and parallel to each other, and the third side connecting the first side and the second side. The light emitting diode chip is disposed on the die bonding area. The terminal connecting portion protrudes from the third side of the first notch of the substrate and is electrically connected to the light emitting diode chip. A second notch and a third notch is defined between the terminal connecting portion and the first side and the second side.

According to one or more embodiments of the invention, the above-mentioned substrate includes a main body layer, a dielectric layer, a circuit layer and a solder resist layer. The dielectric layer is formed on the main body layer, the circuit layer formed on the dielectric layer, and the circuit layer is electrically connected between the terminal connecting portion and the light emitting diode chip. The solder resist layer is formed on the circuit layer.

According to one or more embodiments of the invention, the above-mentioned terminal connecting portion includes a dielectric layer, a circuit layer and a solder resist layer extending from the substrate, and a plurality of conductive terminals electrically connected to the circuit layer and exposed on the surface of the dielectric layer, or simultaneously exposed on the surface of the solder resist layer and the dielectric layer.

According to one or more embodiments of the invention, the main body layer is extending from the substrate and below the dielectric layer of the terminal connecting portion.

According to one or more embodiments of the invention, the above-mentioned light emitting diode package structure further includes an encapsulating layer covering the light emitting diode chip.

According to one or more embodiments of the invention, the above-mentioned encapsulating layer further includes a wavelength conversion material within that can be excited by the light emitted by the light emitting diode chip.

According to one or more embodiments of the invention, the above-mentioned wavelength conversion material includes phosphors.

According to one or more embodiments of the invention, the above-mentioned light emitting diode package structure further includes a frame body surrounding the die bonding area.

According to one or more embodiments of the invention, the above-mentioned light emitting diode chip is a visible light emitting diode chip.

According to one or more embodiments of the invention, the above-mentioned visible light emitting diode chip is a blue light emitting diode chip.

The above-mentioned embodiments compared with the known prior art has the following advantages:

1. In one or more embodiments of the light emitting diode package structure of the present invention, with the terminal connecting portion protruding from the substrate, the light emitting diode package structure can directly bond with connectors corresponding to the terminal connecting portion, without the need for soldering or SMT process, thus reducing manufacturing costs and avoiding damage to the substrate or encapsulating layer due to high temperature soldering.

2. In one or more embodiments of the light emitting diode package structure of the present invention, the light emitting diode package structure may be loaded into a luminaire with the corresponding socket to perform electrical lighting and other tests. Furthermore, if abnormal conditions occur during long-term use of the luminaire using the light emitting diode package structure of the present embodiments, replacement of the light emitting diode package structure can be done directly, and without the need to replace the entire luminaire, waste of resources can be avoided.

It is to be understood that both the foregoing general description and the following detailed description are by examples, and are intended to propose further explanation of the invention as claimed.

### BRIEF DESCRIPTION OF THE DRAWINGS

The invention can be more fully understood by reading the following detailed description of the embodiment, with reference made to the accompanying drawings as follows.

FIG. 1 illustrates a front perspective view of the light emitting diode package structure of the first embodiment of the invention.

FIG. 2 illustrates a rear perspective view of the light emitting diode package structure of the second embodiment of the invention.

FIG. 3 illustrates a front perspective view of the light emitting diode package structure of the third embodiment of the invention.

FIG. 4 illustrates a front perspective view of the light emitting diode package structure of the fourth embodiment of the invention.

FIG. 5 illustrates a front perspective view of the light emitting diode package structure of the fifth embodiment of the invention.

FIG. 6 illustrates a rear perspective view of the light emitting diode package structure of the sixth embodiment of the invention.

FIG. 7 illustrates a perspective front view of the light emitting diode package structure of the seventh embodiment of the invention.

FIG. 8 illustrates a front perspective view of the light emitting diode package structure of the eighth embodiment of the invention.

### DETAILED DESCRIPTION

The following will use drawings to disclose a plurality of embodiments of the invention, for a clear description, many practical details will be explained in the following description. However, one should understand that these practical details are not intended to limit the invention. In other words, in some embodiments of the invention, these practical details are not essential. In addition, to simplify the drawings, some conventional structures and components in the drawings will be illustrated in a simplified schematic way. Furthermore, in each embodiment, the same reference numerals represent the same or similar elements.

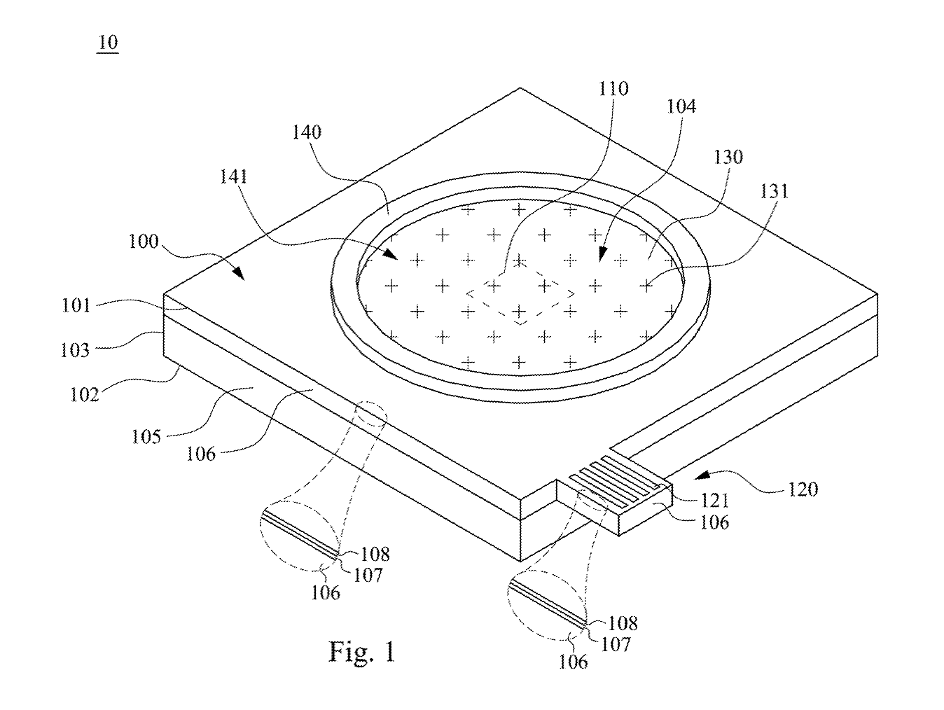

Please refer to FIG. 1, which illustrates a perspective view of the light emitting diode package structure of the first embodiment of the invention. As shown in the figure, the light emitting diode package structure 10 includes a substrate 100, a light emitting diode chip 110, and a terminal connecting portion 120. The Substrate 100 has a first surface 101, a second surface 102 and a side surface 103. The first surface 101 and the second surface 102 are mutually opposite to each other, the side surface 103 surrounds the first surface 101 and the second surface 102, and connects the first surface 101 and the second surface 102.

The first surface 101 has a predetermined die bonding area 104, the light emitting diode chip 110 is disposed on the die bonding area 104. It should be understood that, in actual product application, the first surface 101 may include a plurality of light emitting diode chips 110 respectively disposed on the die bonding area 104, and a plurality of light emitting diode chips 110 can be randomly arranged on the first surface 101.

The light emitting diode chip 110 can be a visible light emitting diode chip 110. In this embodiment, the light emitting diode chip 110 is, but not limited to, a blue light emitting diode chip 110. In other embodiments of the invention, the light emitting diode chip 110 can be a red light, an orange light, a green light, and other color light emitting diode chip 110.

Please refer to FIG. 1, as an example, the light emitting diode chip 110 is a blue light emitting diode chip 110, the light emitting diode package structure 10 further includes an encapsulating layer 130, covering the blue light emitting diode chip 110, wherein the encapsulating layer 130 also includes a wavelength conversion material 131. The wavelength conversion material 131 may be doped with one or more phosphors that can be excited by a wavelength, the phosphors can be excited by the blue light emitted by the blue light emitting diode chip 110 and convert it into other color lights, and mix with the unconverted blue light and form white light.

In the present embodiment, the light emitting diode package structure 10 further includes a frame body 140, the frame body 140 surrounds the die bonding area 104. In other words, the frame body 140 can define a receiving area 141 on the first surface 101 of the substrate 100, the receiving area 141, used for receiving the light emitting diode chip 110 and the encapsulating layer 130, may be circular, rectangular, oval, or any other closed shape.

Please refer to FIG. 1, the terminal connecting portion 120 protrudes from the side surface 103 of the substrate 100, and is electrically connected to the light emitting diode chip 110. More specifically, the substrate 100 of the ht emitting diode package structure 10 may further include a main body layer 105, a dielectric layer 106, a circuit layer 107 and a solder resist layer 108. The dielectric layer 106 is formed on the main body layer 105, the circuit layer 107 is formed on the dielectric layer 106, and the circuit layer 107 is electrically connected between the terminal connecting portion 120 and the light emitting diode chip 110. The solder resist layer 108 is formed on the circuit layer 107 to cover the metal lines on the circuit layer 107.

Please refer to FIG. 1, the terminal connecting portion 120 includes the dielectric layer 106, the circuit layer 107, and the solder resist layer 108 extending from the substrate 100. In other words, the dielectric layer 106, the circuit layer 107 and the solder resist layer 108 of the terminal connecting portion 120 and the dielectric layer 106, the circuit layer 107 and the solder resist layer 108 of the substrate 100 is a integrally formed structure. Here the so-called “integrally formed structure” means that each layer of the terminal connecting portion 120 and the substrate 100 is formed by processing on the same piece of material, the same layer has no seam between the terminal connecting portion 120 and the substrate 100. For example, the dielectric layer 106 of the terminal connecting portion 120 and the substrate 100 is formed by processing on the same type of material, the dielectric layer 106 at the terminal connecting portion 120 and the substrate 100 has no seam between the two. It is worth mentioning that, the terminal connecting portion 120 further includes a plurality of conductive terminals 121, in the present embodiment, the conductive terminal 121 is exposed on the surface of the solder resist layer 108, and is electrically connected to the circuit layer 107 located in the substrate 100.

During actual product application, the light emitting diode package structure 10 of the present embodiment can directly connect with the corresponding socket on an external circuit board via the terminal connecting portion 120, without the need to undergo high temperature processes such as soldering, thus avoiding conventional techniques that damage the encapsulating layer 130 or the substrate 100 of the light emitting diode package structure 10 due to improper soldering and high temperature soldering.

In addition, the light emitting diode package structure 10 of the present embodiment can be immediately loaded into the luminaire with the corresponding socket to perform electrical lighting and other tests, saving the cost of soldering, and if the light emitting effect of the light emitting diode package structure 10 is not as expected during testing, replacement can also be made directly without the need to undergo the desoldering process. Furthermore, if abnormal conditions occur during long-term use of the luminaire using the light emitting diode package structure 10 of the present embodiments, replacement of the light emitting diode package structure 10 can be done directly without the need to replace the entire luminary; waste of resources can be avoided.

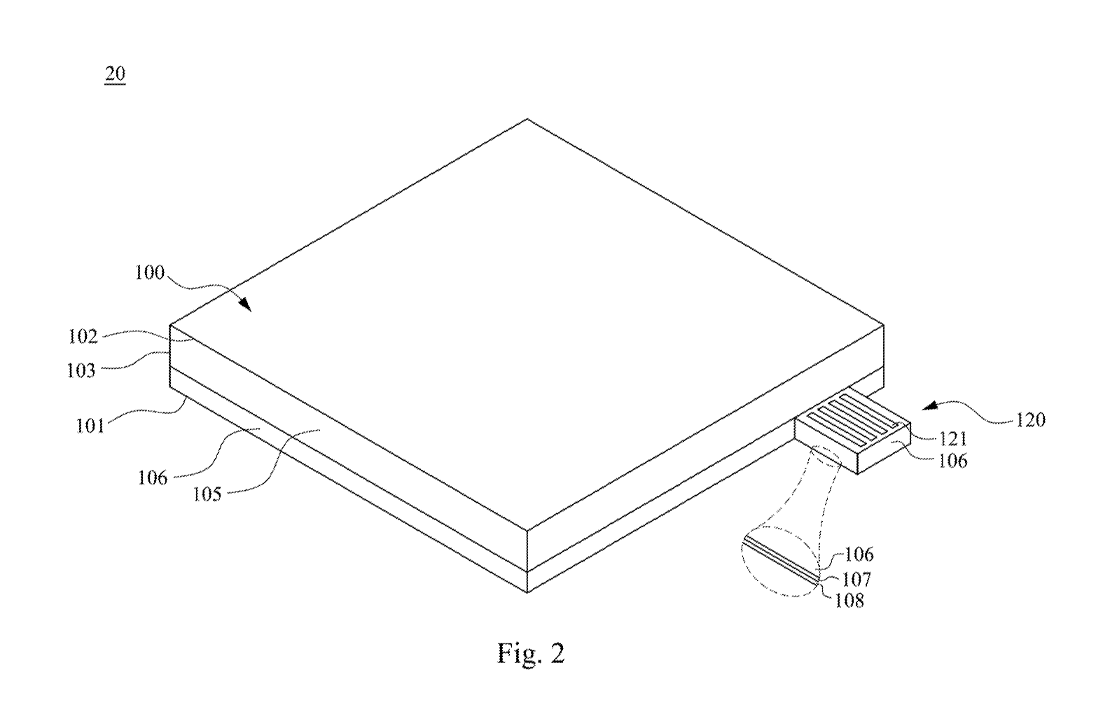

Next, please refer to FIG. 2, which illustrates a perspective view of the light emitting diode package structure of the second embodiment of the invention. As shown in the figure, the difference in the present embodiment and the first embodiment lies in that the plurality of conductive terminals 121 are exposed on the surface of the dielectric layer 106 of the terminal connecting portion 120 of the light emitting diode package structure 20.

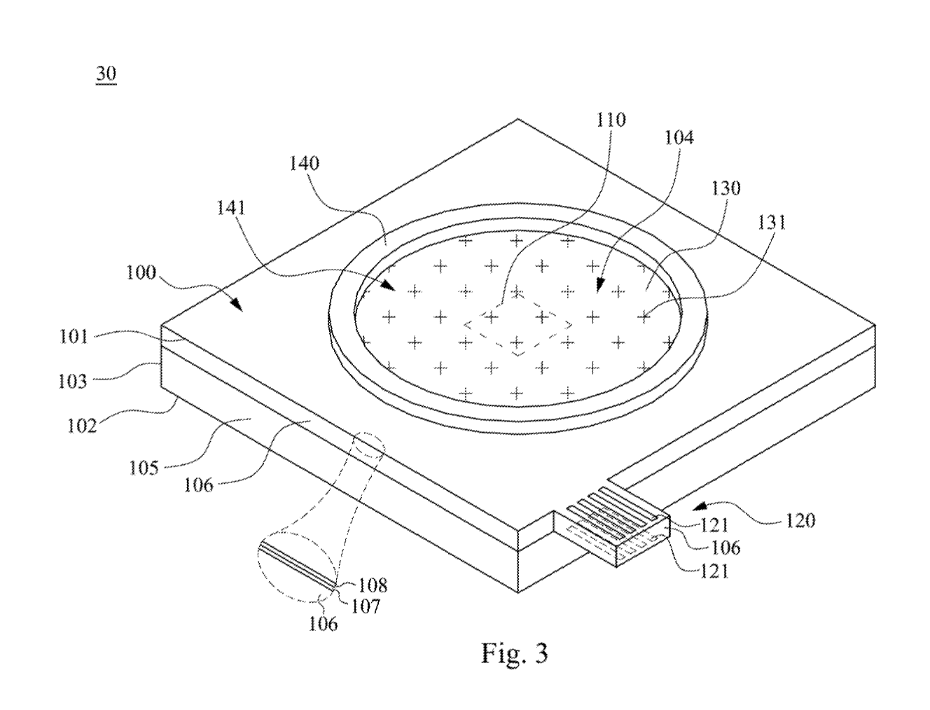

Next, please refer to FIG. 3, which illustrates the light emitting diode package structure of the third embodiment of the invention. As shown in the figure, the plurality of conductive terminals 121 of the light emitting diode package structure 30 of this embodiment can be simultaneously exposed on the solder resist layer 108 and the dielectric layer 106.

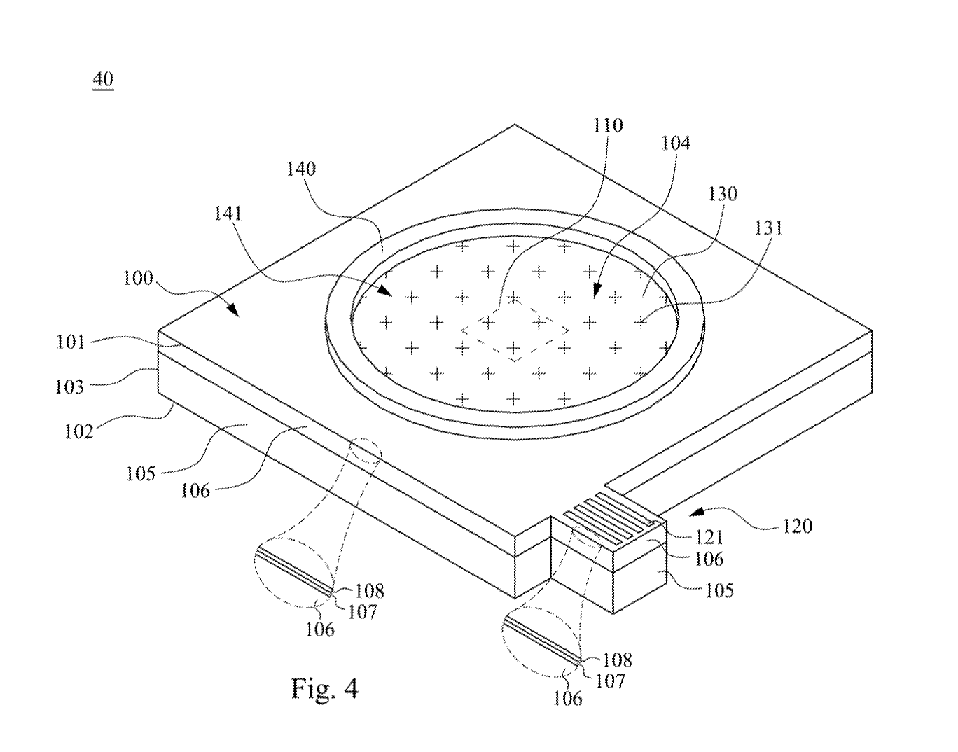

Next, please refer to FIG. 4, which illustrates the light emitting diode package structure of the fourth embodiment of the invention. As shown in the figure, the difference in the present embodiment and the first embodiment lies in that the present embodiment further features the main body layer 105 extending from the substrate 100 and below the dielectric layer 106 of the terminal connecting portion 120 of the light emitting diode package structure 40. In other words, the dielectric layer 106, the circuit layer 107, the solder resist layer 108 and the main body layer 105 of the terminal connecting portion 120 and the dielectric layer 106, the circuit layer 107, the solder resist layer 108 and the main body layer 105 of the substrate 100 of the present embodiment is a integrally formed structure. Here the so-called “integrally formed structure” means that each layer of the terminal connecting portion 120 and the substrate 100 is formed by processing on the same type of material, the same layer has no seam between the terminal connecting portion 120 and the substrate 100. For example, the dielectric layer 106 of the terminal connecting portion 120 and the substrate 100 is formed by processing on the same type of material, the dielectric layer 106 at the terminal connecting portion 120 and the substrate 100 has no seam between the two.

As a result, since the terminal connecting portion 120 of the above-mentioned embodiment can form an integrally formed structure with the substrate 100 therefore it is possible to form the terminal connecting portion 120 protruding on the side surface 103 of the substrate 100 directly in the manufacturing process, with the advantages of ease of manufacture.

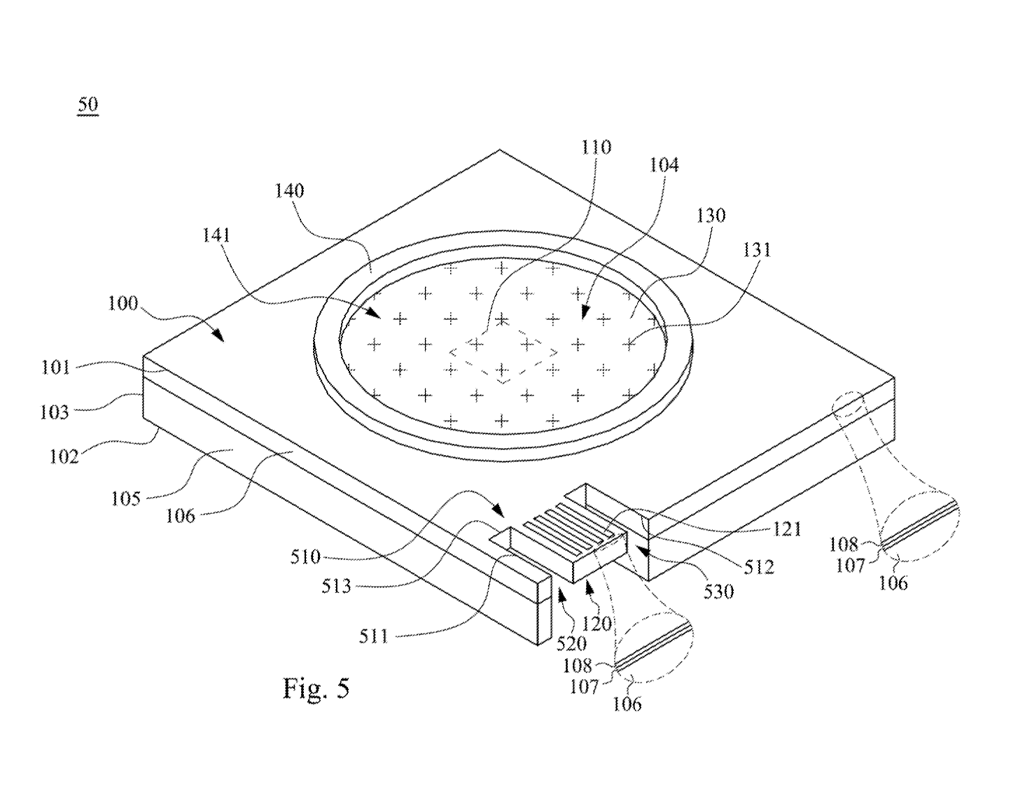

Next, please refer to FIG. 5, which illustrates the perspective view of the light emitting diode package structure of the fifth embodiment of the invention. As shown in the figure, the difference in the present embodiment and the first embodiment lies in that the side surface 103 of the substrate 100 of the light emitting diode package structure 50 of the present embodiment has a first notch 510. The first notch 510 has a first side 511, a second side 512 and a third side 513, in which the first side 511 and the second side 512 are opposite to each other, and the third side 513 is connecting the first side 511 and second side 512.

The terminal connecting portion 120 protrudes from the third side 513 of the first notch 510 of the substrate 100, and define a second notch 520 and a third notch 530 between the terminal connecting portion 120 and the first side 511 and the second side 512. As a result, when the terminal connecting portion 120 of the present embodiment bonds with the corresponding connector socket, the second notch 520 and the third notch 530 can enhance the bonding strength of the terminal connecting portion 120 to the corresponding connector socket.

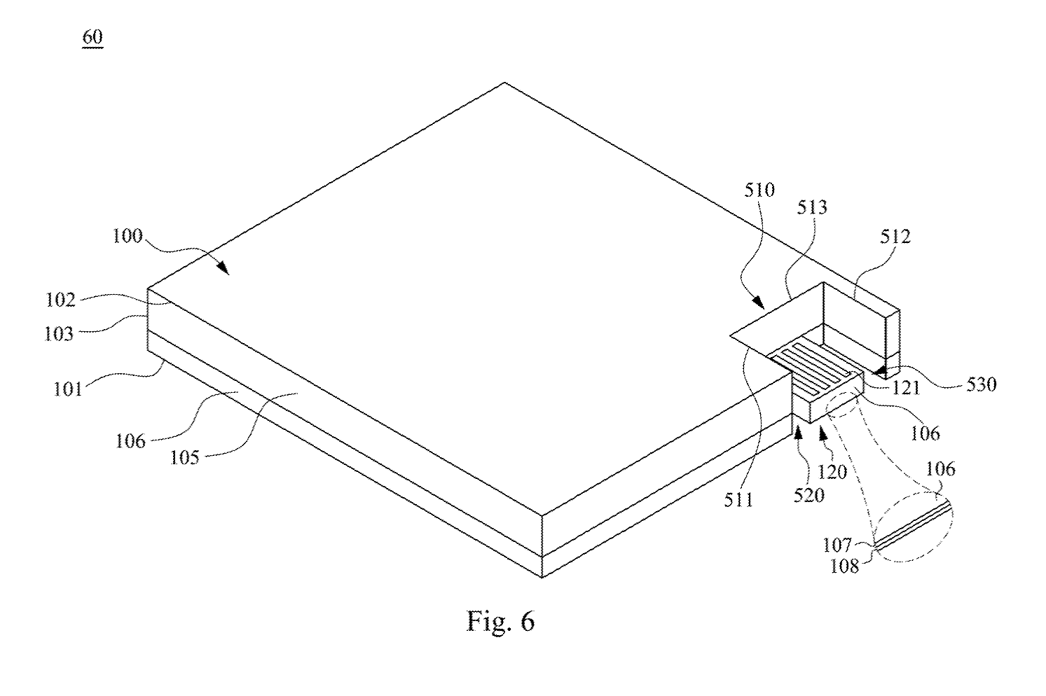

In this embodiment, a plurality of conductive terminals 121 is exposed on, but not limited to, the surface of the solder resist layer 108. Please refer to FIG. 6, which illustrates the perspective view of the sixth embodiment of the invention. As shown in the figure, a plurality of conductive terminals 121 of the light emitting diode package structure 60 can also be exposed on the surface of the dielectric layer 106.

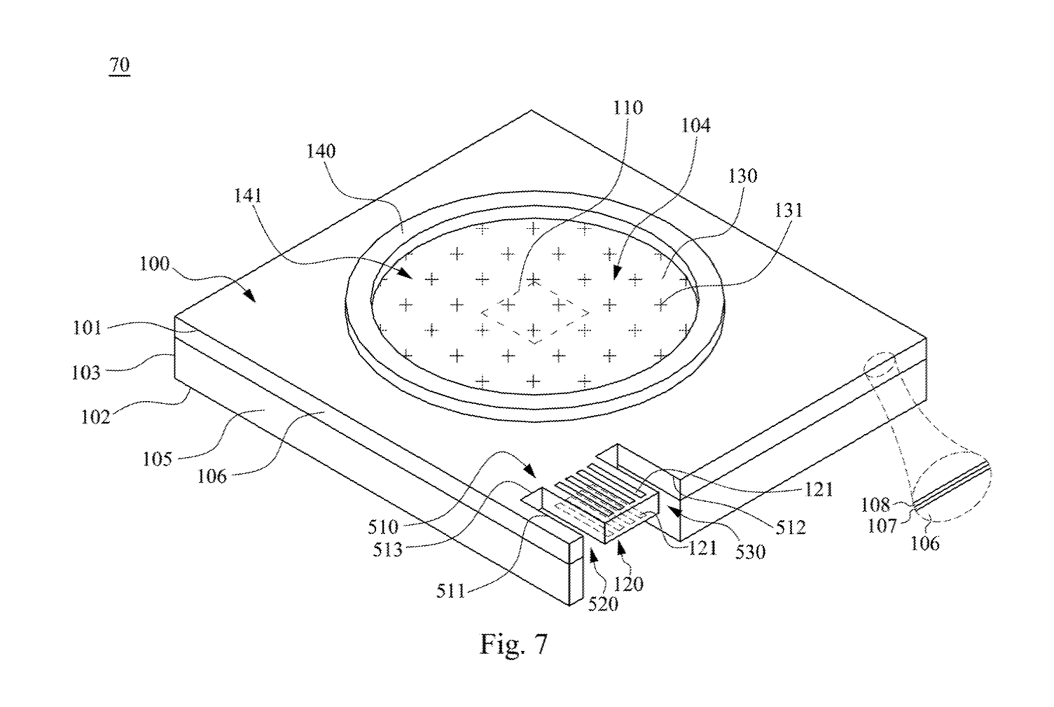

Next, please refer to FIG. 7, which illustrates the light emitting diode package structure of the seventh embodiment of the invention. As shown in the figure, the difference in the light emitting diode package structure 70 of the present embodiment and the sixth embodiment lies in that a plurality of conductive terminals 121 can be simultaneously exposed on the solder resist layer 108 and the dielectric layer 106.

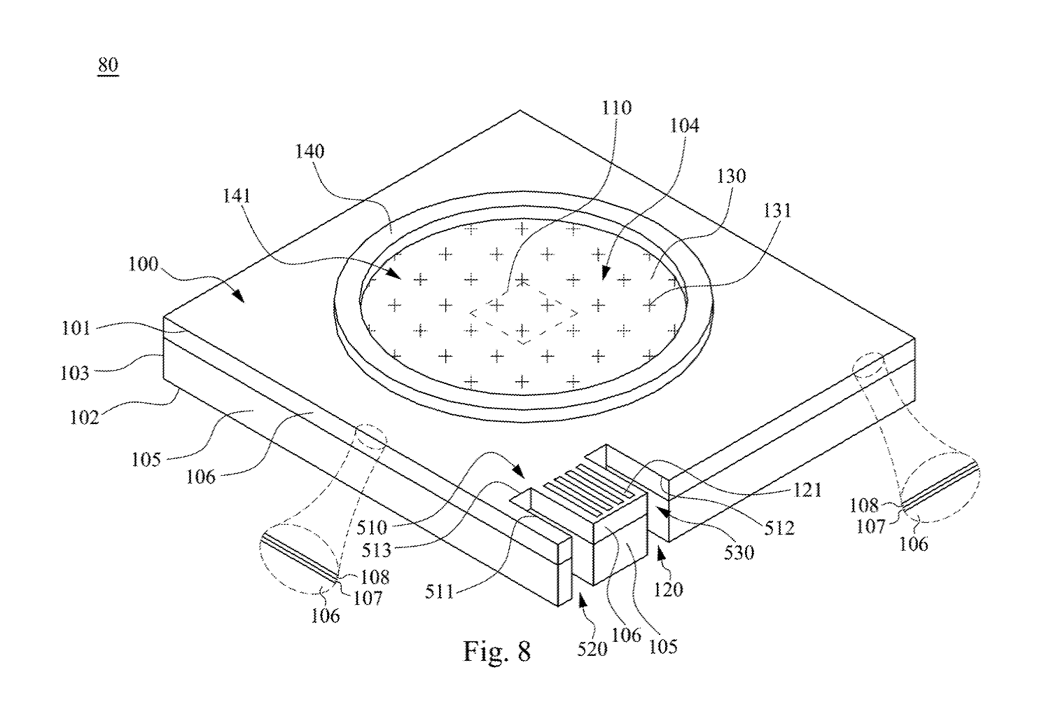

Next, please refer to FIG. 8, which illustrates the light emitting diode package structure of the eighth embodiment of the invention. As shown in the figure, the difference in the present embodiment and the sixth embodiment lies in that the present embodiment further features the main body layer 105 extending from the substrate 100 and beneath the dielectric layer 106 of the terminal connecting portion 120 of the light emitting diode package structure 80. In other words, the dielectric layer 106, the circuit layer 107, the solder resist layer 108 and the main body layer 105 of the terminal connecting portion 120 and the substrate 100 of the present embodiment is a integrally formed structure. Here the so-called “integrally formed structure” means that each layer of the terminal connecting portion 120 and the substrate 100 is formed by processing on the same type of material, the same layer has no seam between the terminal connecting portion 120 and the substrate 100. For example, the dielectric layer 106 of the terminal connecting portion 120 and the substrate 100 is formed by processing on the same type of material, the dielectric layer 106 at the terminal connecting portion 120 and substrate 100 has no seam between the two.

In summary, the light emitting diode package structure of the above-mentioned embodiments that the invention discloses, can form the terminal connecting portion protruding from the side surface of the substrate, which is used to connect to a luminaire with the corresponding connectors or a circuit board, therefore eliminating the need for soldering or production line equipment to connect to the luminaire or circuit board, thus saving manufacturing cost and reducing the probability of damage to the substrate or the encapsulant of the light emitting diode package structure during soldering processes. In addition, during application of the luminaire of the above-mentioned embodiments, if the light emitting effect of the light emitting diode package structure is not as expected, replacement of the light emitting diode package structure can also be made directly, without the need to undergo the desoldering process or the need to replace the entire luminaire, thus reducing waste of resources.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention proposed they fall within the scope of the following claims.

What is claimed is:

1. A light emitting diode package structure, comprising:
a substrate having a first surface and a second surface opposite to each other, and a side surface surrounding and connecting the first surface and the second surface, and a predetermined die bonding area on the first surface;
a light emitting diode chip disposed on the die bonding area; and
a terminal connecting portion protruding from the side surface of the substrate and electrically connected to the light emitting diode chip.

2. The light emitting diode package structure of claim 1, wherein the substrate comprises:
a main body layer;
a dielectric layer formed on the main body layer;
a circuit layer formed on the dielectric layer and electrically connected between the terminal connecting portion and the light emitting diode chip; and
a solder resist layer formed on the circuit layer.

3. The light emitting diode package structure of claim 2, wherein the terminal connecting portion comprises the dielectric layer, the circuit layer and the solder resist layer extending from the substrate, and a plurality of conductive terminals electrically connected to the circuit layer and exposed on the surface of the solder resist layer and/or on the surface of the dielectric layer.

4. The light emitting diode package structure of claim 3, wherein the main body layer is extending from the substrate and below the dielectric layer of the terminal connecting portion.

5. The light emitting diode package structure of claim 1, further comprising an encapsulating layer covering the light emitting diode chip.

6. The light emitting diode package structure of claim 5, wherein the encapsulating layer further comprises a wavelength conversion material that can be excited by the light emitted by the light emitting diode chip.

7. The light emitting diode package structure of claim 6, wherein the wavelength conversion material comprises phosphor.

8. The light emitting diode package structure of claim 7, further comprising a frame body surrounding the die bonding area.

9. The light emitting diode package structure of claim 1, wherein the light emitting diode chip is a visible light emitting diode chip.

10. The light emitting diode package structure of claim 9, wherein the visible light emitting diode chip is a blue light emitting diode chip.

11. A light emitting diode package structure, comprising:
a substrate having a first surface and a second surface opposite to each other, and a side surface surrounding and connecting the first surface and the second surface, wherein the first surface has a predetermined die bonding area, and the side surface has a first notch, the first notch has a first side, a second side, and a third side, wherein the first side and the second side are opposite and parallel to each other, and the third side connecting the first side and the second side;
a light emitting diode chip disposed on the die bonding area; and
a terminal connecting portion electrically connected to the light emitting diode chip and protruding from the third side of the first notch of the substrate, and defining a second notch and a third notch between the terminal connecting portion and the first side and the second side.

12. The light emitting diode package structure of claim 11, wherein the substrate comprises:
a main body layer;
a dielectric layer, formed on the main body layer;
a circuit layer, formed on the dielectric layer, and electrically connected between the terminal connecting portion and the light emitting diode chip; and
a solder resist layer, formed on the circuit layer.

13. The light emitting diode package structure of claim 12, wherein the terminal connecting portion comprises the dielectric layer, the circuit layer and the solder resist layer extending from the substrate, and a plurality of conductive terminals electrically connected to the circuit layer and exposed on the surface of the solder resist layer and/or on the surface of the dielectric layer.

14. The light emitting diode package structure of claim 13, the main body layer is extending from the substrate and below the dielectric layer of the terminal connecting portion.

15. The light emitting diode package structure of claim 11, further comprising an encapsulating layer covering the light emitting diode chip.

16. The light emitting diode package structure of claim 15, wherein the encapsulating layer further comprises a wavelength conversion material that can be excited by the light emitted by the light emitting diode chip.

17. The light emitting diode package structure of claim 16, wherein the wavelength conversion material comprises phosphor.

18. The light emitting diode package structure of claim 17, further comprising a frame body surrounding the die bonding area.

19. The light emitting diode package structure of claim 11, wherein the light emitting diode chip is a visible light emitting diode chip.

20. The light emitting diode package structure of claim 19, wherein the visible light emitting diode chip is a blue light emitting diode chip.
